(19) United States
(12) Patent Application Publication
(10) Pub. No.: US 2026/0129819 A1
(43) Pub. Date: May 7, 2026

(54) Static random access memory structure and manufacturing method thereof

(71) Applicant: UNITED MICROELECTRONICS CORP., Hsin-Chu City (TW)

(72) Inventors: Chun-Hsien Huang, Tainan City (TW); Chien-Hung Chen, Taipei City (TW); Yu-Tse Kuo, Tainan City (TW); Shu-Ru Wang, Taichung City (TW); Chun-Yen Tseng, Tainan City (TW)

(73) Assignee: UNITED MICROELECTRONICS CORP., Hsin-Chu City (TW)

(21) Appl. No.: 18/969,211

(22) Filed: Dec. 4, 2024

(30) Foreign Application Priority Data
Nov. 6, 2024 (TW) 113142450

(51) Int. Cl. H10B 10/00; H10D 84/01; H10D 84/83

(52) U.S. Cl. CPC H10B 10/12; H10D 84/0158; H10D 84/834

(57) ABSTRACT

The invention provides a static random access memory structure, which comprises a silicon substrate, a shallow trench isolation on the silicon substrate, a first fin structure connected with the silicon substrate and protruding from the shallow trench isolation, a first gate structure spanning the first fin structure and parts of the shallow trench isolation, so that the first gate structure covers a top surface and a part of sidewalls of the first fin structure, and forms a pass gate transistor (PG). And a protruding part located directly below the first gate structure and on the shallow trench isolation, the protruding part covers part of the surface of at least one sidewall of the first fin structure, and a top surface of the protruding part is higher than a top surface of the shallow trench isolation.

### BACKGROUND OF THE INVENTION

### 1. Field of the Invention

The invention relates to a static random access memory (SRAM), in particular to a layout pattern of a static random access memory (SRAM) with high efficiency and a manufacturing method thereof.

### 2. Description of the Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer systems as a cache memory.

### SUMMARY OF THE INVENTION

The invention provides a static random access memory structure. The static random access memory structure includes a silicon substrate, a shallow trench isolation located on the silicon substrate, a first fin structure connected to the silicon substrate and protruding from the shallow trench isolation, a first gate structure across the first fin structure and part of the shallow trench isolation, so that the first gate structure covers a top surface and part of sidewalls of the first fin structure, and constitutes a pass gate transistor (PG) of the SRAM, and a protrusion part located directly below the first gate structure and on the shallow trench isolation, covering part of the surface of at least one sidewall of the first fin structure, wherein a top surface of the protrusion part is higher than a top surface of the shallow trench isolation, and a height from the top surface of the shallow trench isolation to the top surface of the first fin structure in a vertical direction is defined as h1, and a height from the top surface of the shallow trench isolation to the top surface of the protrusion part in the vertical direction is defined as h2.

The invention also provides a method for manufacturing a static random access memory structure, which includes the following steps: providing a silicon substrate, forming a shallow trench isolation on the silicon substrate, forming a first fin structure connected to the silicon substrate and protruding from the shallow trench isolation, forming a first gate structure across the first fin structure and part of the shallow trench isolation, so that the first gate structure covers a top surface and part of sidewalls of the first fin structure, and constitutes a pass gate transistor (PG) of the SRAM, and forming a protrusion part directly below the first gate structure and on the shallow trench isolation, covering part of the surface of at least one sidewall of the first fin structure, wherein a top surface of the protrusion part is higher than a top surface of the shallow trench isolation, and a height from the top surface of the shallow trench isolation to the top surface of the first fin structure in a vertical direction is defined as h1, and a height from the top surface of the shallow trench isolation to the top surface of the protrusion part in the vertical direction is defined as h2.

The invention is characterized in that in order to improve the device quality, it is necessary to increase the ratio of the turn-on current of the PD transistor to the turn-on current of the PG transistor, but the width of the fin structure formed by sidewall pattern transfer cannot be adjusted only by the mask pattern. Therefore, the invention adjusts the channel width of the transistor by changing the shallow trench isolation around the fin structure or the height of the protrusion part. More specifically, the invention uses etching process to reduce shallow trench isolation beside other transistors except the PG transistor, or uses another mask layer to cover the PG fin structure, so that when the gate structure is covered on the fin structure, the channel width of the PD transistor will be larger the channel width of the PG transistor, thereby reducing the turn-on current of the PG transistor and achieving the purpose of improving the beta value and static noise margin of SRAM.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a circuit diagram of a six transistor SRAM (6T-SRAM) cell of the present invention.

FIG. 2 is a layout diagram of 6T-SRAM according to an embodiment of the present invention.

FIG. 3, FIG. 4 and FIG. 5 are schematic structural views for forming a PG transistor and a PD transistor according to a first embodiment of the present invention.

FIG. 6, FIG. 7 and to FIG. 8 are schematic structural views for forming a PG transistor and a PD transistor according to a second embodiment of the present invention.

FIG. 9 is a schematic structural diagram of a PG transistor according to a third embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

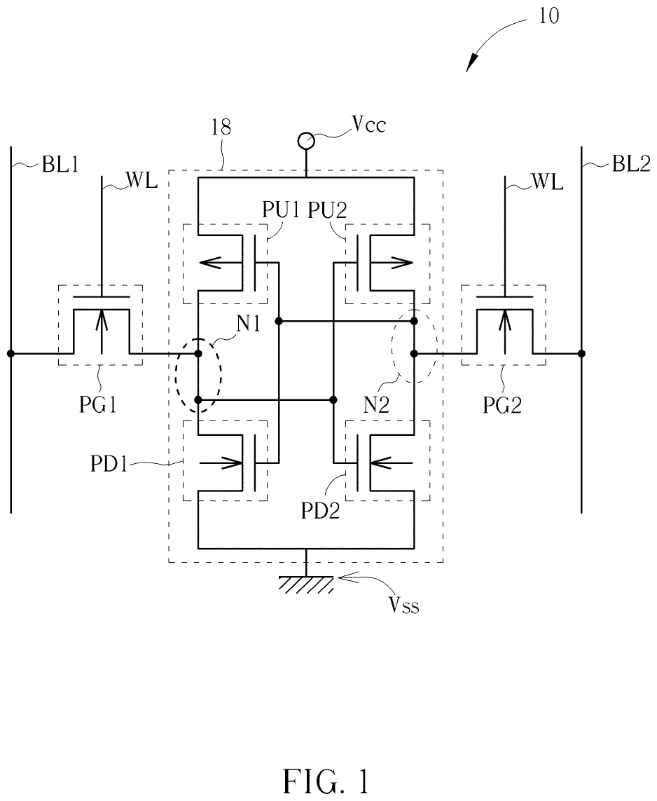

FIG. 1 is a circuit diagram of a set of six-transistor SRAM (6T-SRAM) memory cell in the SRAM of the present invention. Referring to FIG. 1, in this embodiment, each 6T-SRAM memory cell 10 is preferably composed of a first pull-up transistor PU1, a second pull-up transistor PU2, a first pull-down transistor PD1, a second pull-down transistor PD2, a first pass gate transistor PG1 and a second pass gate transistor PG2 form a flip-flop, in which the first pull-up transistor PU1 and the second pull-up transistor PU2, the first pull-down transistor PD1 and the second pull-down transistor PD2 form a latch circuit 22, so that data can be latched at a storage node N1 or N2. In addition, the first pull-up transistor PU1 and the second pull-up transistor PU2 are used as active loads, and they can also be replaced by common resistors as pull-up transistors, in this case, four-transistor static random access memory (4T-SRAM). In addition, in this embodiment, the sources of the first pull-up transistor PU1 and the second pull-up transistor PU2 are electrically connected to a voltage source Vcc, and the sources of the first pull-down transistor PD1 and the second pull-down transistor PD2 are electrically connected to a voltage source Vss.

In an embodiment, the first pull-up transistor PU1 and the second pull-up transistor PU2 of the 6T-SRAM memory cell 10 are composed of P-type metal oxide semiconductor (PMOS) transistors. The first pull-down transistor PD1, the second pull-down transistor PD2, the first pass gate transistor PG1 and the second pass gate transistor PG2 are composed of N-type metal oxide semiconductor (NMOS) transistors, but the present invention is not limited to this. The first pull-up transistor PU1 and the first pull-down transistor PD1 form an inverter, and the two ends of the series circuit formed by them are respectively coupled to a voltage source Vcc and a voltage source Vss; Similarly, the second pull-up transistor PU2 and the second pull-down transistor PD2 form another inverter, and the two ends of the series circuit formed by these two transistors are respectively coupled to the voltage source Vcc and the voltage source Vss. The two inverters are coupled to each other to store data.

In addition, at the storage node N1, the gate of the second pull-down transistor PD2, the gate of the second pull-up transistor PU2, and the drain of the pull-down transistor PD1, the drain of the first pull-up transistor PU1 and the drain of the first pass gate transistor PG1 are electrically connected to each other; Similarly, at the storage node N2, the gate of the first pull-down transistor PD1, the gate of the first pull-up transistor PU1, the drain of the second pull-down transistor PD2, the drain of the second pull-up transistor PU2 and the drain of the second pass gate transistor PG2 are electrically connected to each other. The gates of the first pass gate transistor PG1 and the second pass gate transistor PG2 are respectively coupled to a word line WL, and the sources of the first pass gate transistor PG1 and the second pass gate transistor PG2 are respectively coupled to the corresponding bit lines BL1 and BL2.

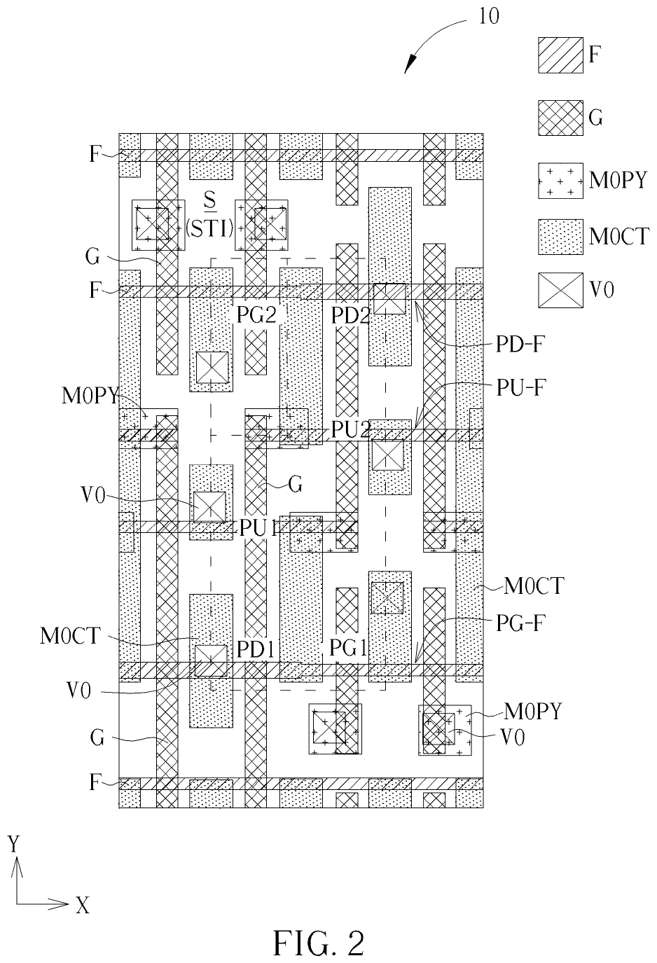

FIG. 2 is a layout diagram of a static random access memory according to the first preferred embodiment of the present invention. In this embodiment, as shown in FIG. 2, the 6T-SRAM memory cell 10 is disposed on a substrate S, such as a silicon substrate or a silicon-on-insulator (SOI) substrate. The substrate S may be a planar structure or provided with a plurality of fin structures F, and a plurality of gate structures G are disposed on the substrate S. In other embodiments of the present invention, it can also be applied to planar SRAM, which means that the doped regions are formed in the substrate instead of the fin structures, and it also belongs to the scope of the present invention.

In addition, the layout of FIG. 2 also includes a plurality of metal layers, where the metal layer partially connecting the gates of each transistor is defined as MOPY, and the metal layer connecting the source/drain of each transistor is defined as MOCT. In FIG. 2, the metal layer MOPY and the metal layer MOCT are represented by different shading. However, the difference between the metal layer MOPY and the metal layer MOCT is that the connected components are different. Both of them actually belong to metal layers and can contain the same material, but the present invention is not limited thereto. FIG. 2 also includes a plurality of contact plugs (via) V0, wherein the contact plugs V0 are used to connect the metal layers MOPY and MOCT to other conductive layers (such as M1, V1, M2, etc., which are common in semiconductor manufacturing processes) formed subsequently.

In the layout pattern of the present invention, a three-dimensional SRAM is taken as an example (that is, fin structures F are formed instead of planar doped regions). As shown in FIG. 2, on the substrate S, except the positions that the fin structures F, the gate structures G, the metal layers MOPY, the metal layers MOCT and the contact plugs V0 are formed, the rest of the substrate S is covered with an insulating layer, such as a shallow trench isolation (STI), to isolate various electronic components (such as transistors) and avoid short circuit. In addition, each gate structure G straddles part of the fin structure F to form transistors (for example, the first pull-up transistor PU1, the second pull-up transistor PU2, the first pull-down transistor PD1, the second pull-down transistor PD2, the first pass gate transistor PG1 and the second pass gate transistor PG2). For clarity of the drawing, the positions of the above transistors are directly marked on FIG. 2, especially at the intersection of the gate structure G and the fin structure F.

As shown in FIG. 2, for the convenience of the following description, the fin structures F crossed by the gate structures G in different transistors in the 6T-SRAM memory cell 10 are defined as different names, including: in the first pull-up transistor PU1 and the second pull-up transistor PU2, the fin structures F crossed by the gate structures G are defined as the PU fin structures (PU-F), in the first pull-down transistor PD1 and the second pull-down transistor PD2, the fin structure F crossed by the gate structure G is defined as the PD fin structure (PD-F), while in the first pass gate transistor PG1 and the second pass gate transistor PG2, the fin structure F crossed by the gate structure G is defined as the PG fin structure (PG-F). Significantly, the PD fin structure (PD-F) and the PG fin structure (PG-F) may be different parts of one same fin structure, that is to say, one part of a fin structure F is defined as the PD fin structure (PD-F), while the other part is defined as the PG fin structure (PG-F). In addition, the first pull-down transistor PD1 and the second pull-down transistor PD2 are collectively referred to as PD transistors, and the first pass gate transistor PG1 and the second pass gate transistor PG2 are collectively referred to as PG transistors. That is to say, the PD transistor described in the following paragraph refers to either or both of the first pull-down transistor PD1 and the second pull-down transistor PD2, and the PG transistor refers to either or both of the first pass gate transistor PG1 and the second pass gate transistor PG2.

One of the purposes of the present invention is to improve the static noise margin (SNM) of a SRAM, where the static noise margin is related to the beta ratio (β ratio) of SRAM. In which the beta ratio is equal to the ratio of the turn-on current of the transistor PD to the turn-on current of the transistor PG. In other words, if the turn-on current of transistor PD is increased or the turn-on current of transistor PG is decreased, the beta ratio and static noise margin can be increased.

According to the following transistor equation 1, it can be found that the current passing through the transistor is proportional to the channel width W, and when the gate structure G crosses the fin structure F, the channel width W of the transistor is related to the width of the fin structure F. In other words, if the width of the gate structure F is increased, the current through the transistor will also be increased, whereas if the width of the gate structure F is decreased, the current through the transistor will also be decreased.

$$I = {μ}_{n} {C}_{ox} W / L [ ( {V}_{GS} - {V}_{th} ) {V}_{DS} - {{V}^{2}}_{DS} / 2 ] \qquad Equation 1$$

wherein:
I is the current passing through the transistor;
W is the gate width (the channel width) of the transistor;
L is the gate length (the channel length) of the transistor;
μₙ is the carrier mobility;
Cₒₓ is the unit capacitance of the gate oxide layer;
V_{GS} is the voltage from the gate to the source;
V_{DS} is the voltage from the drain to the source; and
Vₜₕ is the threshold voltage.

As mentioned above, if the width of the PD fin structure (PD-F) can be increased or the width of the PG fin structure (PG-F) can be decreased, the beta ratio can be increased. However, with the progress of the manufacturing process, most of the current fin structures are formed by sidewall image transfer (SIT) process, so the width of the fin structures cannot be directly controlled by changing the mask pattern, and other ways are needed to achieve the purpose of changing the width of the fin structure.

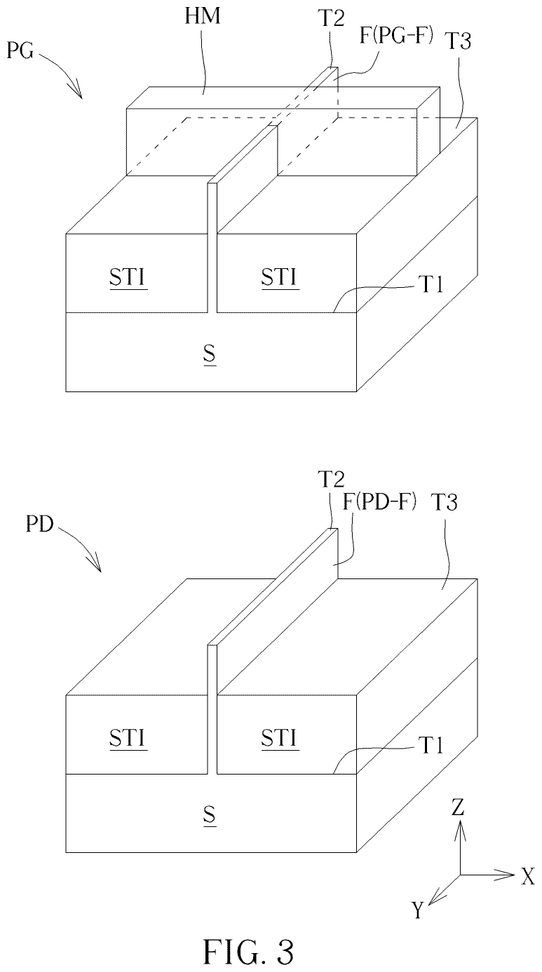

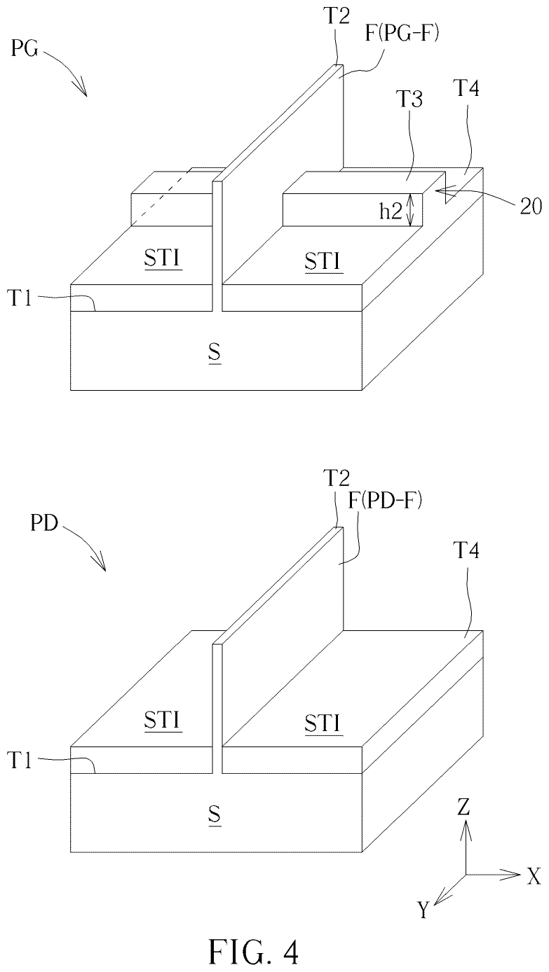

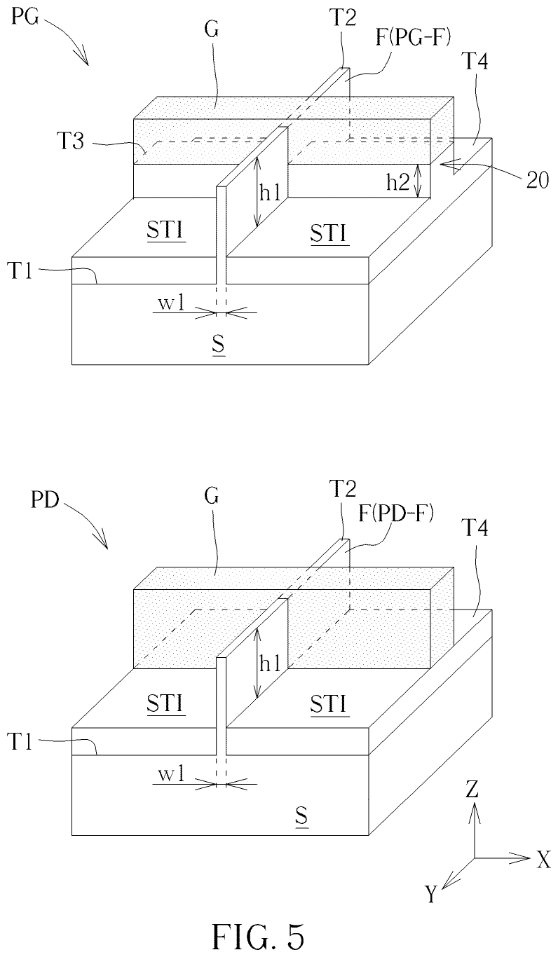

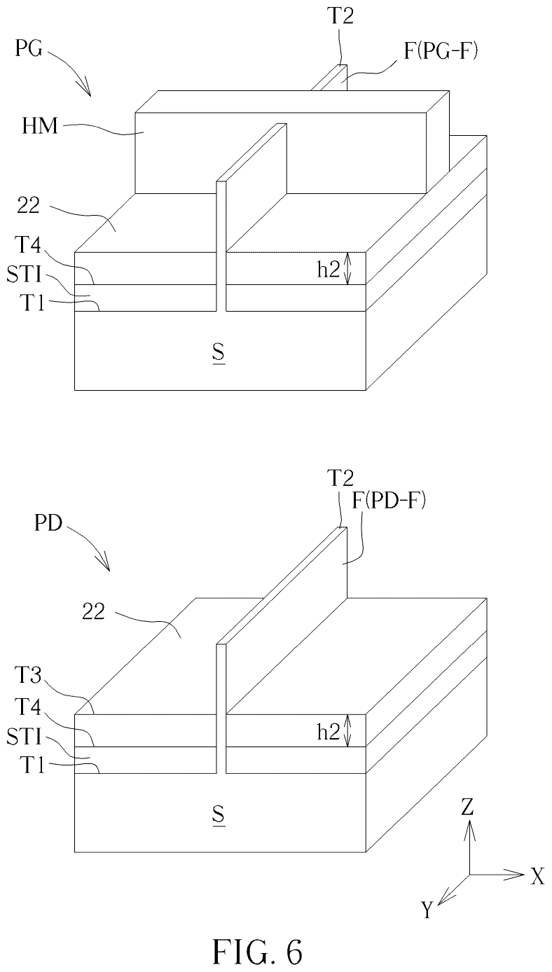

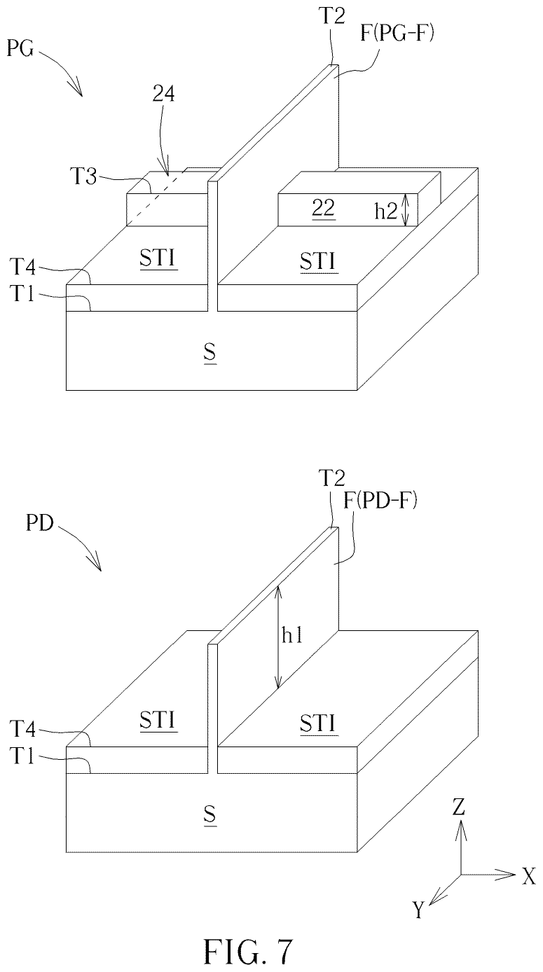

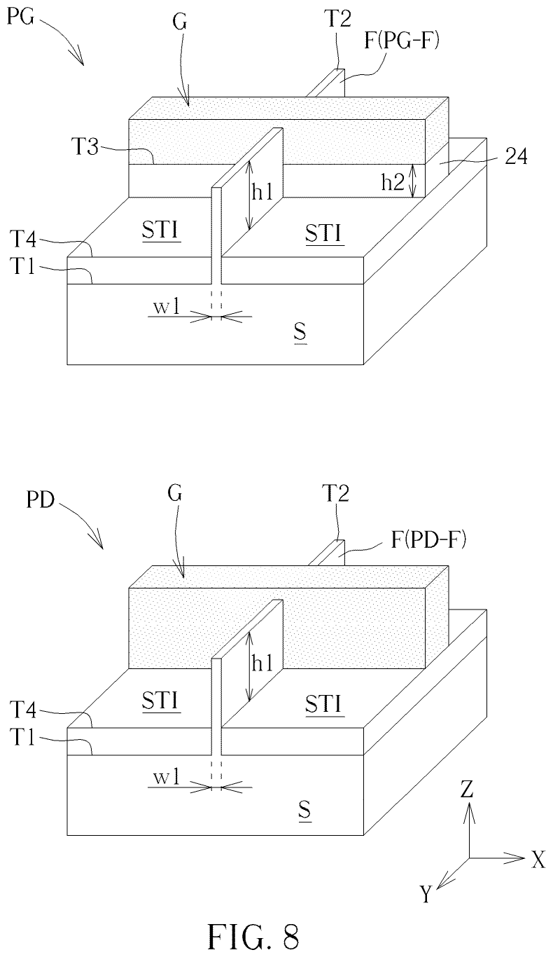

Therefore, the invention reduces the channel width of the PG transistor by adjusting the height of the shallow trench isolation around the fin structure of the PG transistor, or covering the shallow trench isolation with another mask layer, so as to reduce the current value passing through the PG transistor and improve the beta value. More specifically, please refer to the following FIG. 3 to FIG. 8, wherein FIGS. 3 to 5 show the structural schematic diagrams for forming a PG transistor and a PD transistor according to the first embodiment of the present invention, and FIGS. 6 to 8 show the structural schematic diagrams for forming a PG transistor and a PD transistor according to the second embodiment of the present invention, wherein the upper half of FIGS. 3 to 8 shows the structural schematic diagram of the PG transistor and the lower half shows the structural schematic diagram of the PD transistor.

First, please refer to FIGS. 3 to 5. As shown in FIG. 3, firstly, a fin structure F is formed on a substrate S, which includes the fin structure PG-F and the fin structure PD-F, and then a shallow trench isolation STI is formed on the substrate S, wherein the fin structure F protrudes from the surface of the shallow trench isolation STI. In the step shown in FIG. 3, the height of fin structure F in the PG transistor and the height of fin structure F in the PD transistor are preferably the same, and the thickness of shallow trench isolation STI has a uniform thickness. It is worth noting that the height of the fin structure defined here refers to the height from the top surface T1 of the substrate S to the top surface T2 of the fin structure F in the vertical direction (for example, Z direction), while the thickness of shallow trench isolation STI refers to the height from the top surface T1 of the substrate S to the top surface T3 of shallow trench isolation in the vertical direction.

Next, a mask layer HM is covered on the fin structure PG-F of the PG transistor, but the mask layer HM is not covered on the fin structure PD-F of the PD transistor. The material of the mask layer HM is, for example, silicon nitride or silicon oxynitride, but it is not limited to this. The position of the mask layer HM overlaps with the position of the gate structure to be formed in advance. The purpose of forming the mask layer HM here is to make the channel width of the PD transistor larger than that of the PG transistor. More specifically, in the following step, an etching process will be performed to etch the shallow trench isolation around the PD transistor. As a result, the exposed height of the fin structure PD-F in the PD transistor will increase, resulting in a larger channel width of the PD transistor, but the channel width of the PG transistor will remain unchanged. The details will be described in the following paragraphs.

Then, as shown in FIG. 4, an etching step is performed to remove part of shallow trench isolation STI of the PG transistor and PD transistor not covered by the mask layer HM, and then the mask layer HM is removed. After this step is completed, the shallow trench isolation STI of the PG transistor will include a protrusion part 20, wherein the material of the protrusion part 20 is the same as that of the shallow trench isolation STI, and the protrusion part 20 and the shallow trench isolation STI are integrally formed structure (both of them contain the same material and are directly connected). It is worth noting that the extension direction (for example, X direction) of the protrusion part 20 is the same as that of the gate structure to be formed in the future, and their positions overlap with each other. In other words, for the PG transistor, the gate structure to be formed in the following steps will be located on the protrusion part 20, while for the PD transistor, the gate structure to be formed in the following steps will be located on the shallow trench isolation STI. Here, the top surface of the etched shallow trench isolation STI is defined as T4, where the height h2 of the protrusion part is equal to the height from the top surface T4 to the top surface T3 in the vertical direction.

Then, as shown in FIG. 5, gate structure G are formed to cross the fin structure PG-F of the PG transistor and the fin structure PD-F of the PD transistor. The gate structures G may include multiple material layers, such as a gate oxide layer, a high dielectric constant dielectric layer, a work function metal layer, a barrier layer, a low-resistance metal layer and the like. The material of the gate oxide layer is, for example, silicon oxide, and the dielectric layer with high dielectric constant is, for example, selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta2O₉, SBT), lead zirconate titanate (PbZrxTi₁₋ₓO₃, PZT), barium strontium titanate (BaxSr₁-xTiO₃, BST) or a combination thereof. The work function metal layer is, for example, titanium aluminide (TiAl), zirconium aluminide (ZrAl), tungsten aluminide (WAI), tantalum aluminide (TaAl), hafnium aluminide (HfAl) or TiAlC (titanium aluminum carbide), titanium nitride (TiN), tantalum nitride (TaN) or tantalum carbide (TaC), but not limited thereto. The material of the barrier layer may include titanium (Ti), titanium nitride (TiN), tantalum (Ta), tantalum nitride (TaN) and other materials. The low-resistance metal layer can be selected from low-resistance materials such as copper (Cu), aluminum (Al), tungsten (W), titanium aluminum alloy (TiAl), cobalt tungsten phosphide (CoWP) or their combinations. Other methods for forming the gate structure G are known in the art, and will not be described in detail in this paragraph.

As shown in FIG. 5, the gate structure G spans the fin structure PG-F of the PG transistor and the fin structure PD-F of the PD transistor. Because the PG transistor contains the protrusion part 20, and the PD transistor does not contain the protrusion part 20, the exposed part of the fin structure PG-F of the PG transistor is less, resulting in the channel width of the PD transistor being larger than that of the PG transistor. Specifically, the height at which the fin structure PD-F in the PD transistor in FIG. 5 protrudes from the shallow trench isolation STI surface is defined as h1, where the height h1 is equal to the vertical distance from the top surface T4 to the top surface T2, and the widths of the fin structure PD-F and the fin structure PG-F are defined as w1 (the widths of the two fin structures should be the same). For the PD transistor, the gate structure G covers the top surface and two sidewalls of the fin structure, so the channel width is w1+2h1. On the other hand, since the PG transistor includes the protruding portion 20, for the PG transistor, the sidewall height of the fin structure PG-F covered by the gate structure G is h1−h2, that is, the channel width of the PG transistor is w1+2(h1−h2).

That is, in the first embodiment of the present invention, the shallow trench isolation STI next to the PG transistor contains the protrusion part 20, while the shallow trench isolation STI next to the PD transistor does not contain the protrusion part 20, thereby reducing the exposure height of the fin structure PG-F of the PG transistor (or increasing the exposure height of the fin structure PD-F of the PD transistor). Therefore, the current value through the PD transistor will be greater than the current value through the PG transistor, so as to improve the beta value and static noise margin.

The following description will detail the different embodiments of the present invention. To simplify the description, the following description will detail the dissimilarities among the different embodiments and the identical features will not be redundantly described. In order to compare the differences between the embodiments easily, the identical components in each of the following embodiments are marked with identical symbols.

Please refer to FIGS. 6 to 8. As shown in FIG. 6, in another embodiment of the present invention, after the fin structure F and the shallow trench isolation STI are completed, another material layer 22 can be formed on the shallow trench isolation STI. The material layer 22 may be the same as or different from the shallow trench isolation STI, but it should be an insulating material, such as silicon oxide, silicon nitride, silicon oxynitride, etc., but not limited thereto. Then, a mask layer HM is formed on the material layer 22, and the material of the mask layer HM is preferably different from that of the material layer 22, such as, but not limited to, silicon oxide, silicon nitride, silicon oxynitride, etc.

Then, as shown in FIG. 7, an etching step is performed to completely remove the material layer 22 next to the PD transistor, but leave the material layer 22 covered by the mask layer HM, and then remove the mask layer HM. After this step, a protrusion part 24 is formed next to the PG transistor, where the protrusion part 24 is located on the shallow trench isolation STI. Similar to the protrusion part 20 mentioned above, the protrusion part 24 of this embodiment also has the effect of adjusting the channel width of the transistor. Specifically, as shown in FIG. 8, gate structures G are formed to straddle the fin structures PD-F and PG-F, respectively. Since the PG transistor contains the protrusion part 24 and the PD transistor does not contains the protrusion part 24, the channel width of the PG transistor will be smaller than the channel width of the PD transistor after the gate structures G are formed. In more detail, please refer to FIGS. 6 to 8. In this embodiment, the top surface of the substrate S is defined as T1, the top surface of the fin structure F is defined as T2, the top surface of the protrusion part 24 or the material layer 22 is defined as T3, the top surface of the shallow trench isolation STI is defined as T4, the width of the fin structure F is defined as w1, and the exposed height of the fin structure PD-F of the PD transistor is h1 (that is, the height from the top surface T4 to the top surface T2 in the vertical direction). As can be seen from FIG. 8, for the PD transistor, the gate structure G covers the top surface and two sidewalls of the fin structure, so the channel width is w1+2h1. On the other hand, since the PG transistor includes the protruding portion 24, for the PG transistor, the height of the sidewall of the fin structure PG-F covered by the gate structure G is h1−h2, that is, the channel width of the PG transistor is w1+2 (h1−h2). In this way, the current value through the PD transistor will be greater than the current value through the PG transistor, so as to improve the beta value and static noise margin.

The main difference between this embodiment and the above-mentioned first embodiment is that in the first embodiment, shallow trench isolation STI is directly etched and the position of the protrusion part 20 is defined, while in the second embodiment, a material layer 22 is formed and etched to form the protrusion part 24. Therefore, in the first embodiment, the shallow trench isolation STI and the protrusion part 20 are integrally formed structure, while in the second embodiment, the shallow trench isolation STI and the protrusion part 24 are separately formed. However, in the second embodiment, the materials of the shallow trench isolation STI and the protrusion part 24 may be the same or different, which are within the scope of the present invention.

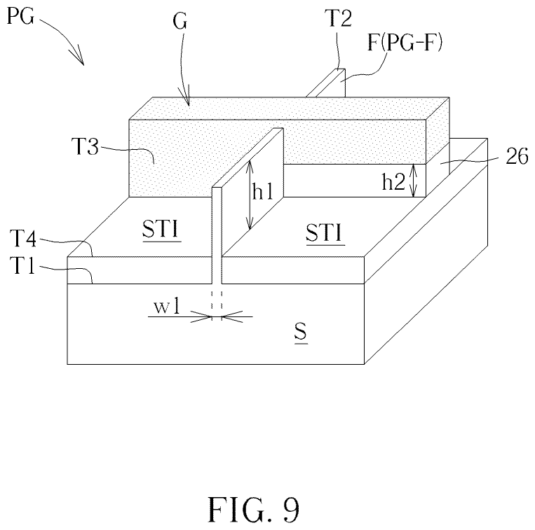

In the above two embodiments, the protrusion part 20 (or protrusion part 24) covers the two sidewalls of the fin structure PG-F, so the channel width of the PG transistor is w1+2 (h1−h2) after the gate structures G are formed. However, in other embodiments of the present invention, by adjusting the position of the mask layer HM, the protrusion parts can be formed only on one sidewall of the fin structure F, and not on the other sidewall. Please refer to FIG. 9, which shows the structural schematic diagram of a PG transistor according to a third embodiment of the present invention. As shown in FIG. 9, the characteristics of most elements in this embodiment are similar to those of the first embodiment or the second embodiment, so the characteristics of these elements are not described in detail in this paragraph. In this embodiment, the protrusion part 26 is formed on the shallow trench isolation STI, and the protrusion part 26 only covers one of the sidewalls of the fin structure PG-F. Therefore, the exposed heights of the two sidewalls of the fin structure PG-F are different. For the PG transistor, the gate structure G spans the top surface and two sidewalls of the fin structure PG-F, and the channel width of the PG transistor is w1+2h1−h2, i.e., w1+h1+(h1−h2), where h1 is the exposed height of the fin structure PD-F of the PD transistor (that is, the vertical height from the top surface of the shallow trench isolation to the top surface of the fin structure PD-F), and h2 is the height of the protrusion part 26 (that is, the top surface of the shallow trench isolation to the protrusion part 26). In this embodiment, only the channel width of one side of the fin structure can be finely adjusted, so that the process parameters can be adjusted more flexibly.

In addition, in the above embodiment, although only one fin structure is drawn in each transistor, in other embodiments of the present invention, a transistor may include multiple fin structures, that is, the gate structure can span multiple fin structures side by side at the same time to form a transistor, and this embodiment is also within the scope of the present invention.

Based on the above description and drawings, the present invention provides a static random access memory structure, which comprises a silicon substrate S, a shallow trench isolation STI located on the silicon substrate S, a first fin structure PG-F connected with the silicon substrate S and protruding from the shallow trench isolation STI, a first gate structure G crossing the first fin structure PG-F and part of the shallow trench isolation STI, so that the first gate structure G covers a top surface and partial sidewalls of the first fin structure PG-F and forms a pass gate transistor (PG) of the SRAM, a protrusion part (20, 24 or 26) located directly below the first gate structure G and on the shallow trench isolation STI, the protrusion part (20, 24 or 26) covers part of the surface of at least one sidewall of the first fin structure PG-F, and a top surface of the protrusion part (20, 24 or 26) is higher than the shallow trench isolation STI. The vertical height from the top surface of shallow trench isolation STI to the top surface of the first fin structure PG-F is defined as h1, and the vertical height from the top surface of shallow trench isolation STI to the top surface of the protrusion part (20, 24 or 26) is defined as h2.

In some embodiments of the present invention, as viewed from a cross section view, the protrusion parts (20, or 24) cover part of the sidewalls of the first fin structure PG-F, wherein the top width of the first fin structure PG-F is defined as w1, and the effective channel width of the pass gate transistor PG formed by the first gate structure G covering the first fin structure PG-F is w1+2 (h1−h2).

In some embodiments of the present invention, as viewed from a cross-sectional view (please refer to the cross-sectional structure in FIG. 9), the protrusion part 26 only covers part of the surface of one sidewall of the first fin structure PG-F, wherein the top width of the first fin structure PG-F is defined as w1, and the effective channel width of the pass gate transistor PG formed by the first gate structure G covering the first fin structure PG-F is w1+2h1−h2.

In some embodiments of the present invention, a second fin structure PD-F is connected to the silicon substrate and protrudes from the shallow trench isolation STI, and a second gate structure G spans the second fin structure PD-F and part of the shallow trench isolation STI, so that the second gate structure G covers a top surface and partial sidewalls of the second fin structure PD-F and forms a pull-down transistor (PD) of the SRAM.

In some embodiments of the present invention, there is no protrusion part (20, 24 or 26) between a region directly below the second gate structure G of the pull-down transistor PD and the shallow trench isolation STI, wherein the top surface T2 of the first fin structure PG-F and the top surface T2 of the second fin structure PD-F are aligned with each other in a horizontal direction, and a bottom surface of the first fin structure PG-F (i.e., the top surface T1 of the substrate S) and a bottom surface of the second fin structure PD-F are aligned with each other in the horizontal direction.

In some embodiments of the present invention, the width of the top surface of the second fin structure PD-F is defined as w1, the height from the top surface of the shallow trench isolation STI to the top surface of the second fin structure PD-F in the vertical direction is defined as h1, and the effective channel width of the pull-down transistor PD formed by the second gate structure G covering the second fin structure PD-F is w1+2h1.

In some embodiments of the present invention, the condition of 0<h2/h1<0.5 is satisfied.

In some embodiments of the present invention, the beta value can be increased by adjusting the channel width of the PD transistor and the PD transistor, and the beta value is defined as B, where the preferred range of β is 1<β≤2, but it is not limited to this.

In some embodiments of the present invention, the material of the protrusion part (24 or 26) is different from that of the shallow trench isolation STI.

In some embodiments of the present invention, the material of the protrusion part 20 is the same as that of the shallow trench isolation STI, and the protrusion part 20 and the shallow trench isolation STI are integrally formed structure.

The invention also provides a method for manufacturing a static random access memory structure, which comprises the following steps: providing a silicon substrate S, forming a shallow trench isolation STI located on the silicon substrate S, forming a first fin structure PG-F connected with the silicon substrate S and protruding from the shallow trench isolation STI, forming a first gate structure G crossing the first fin structure PG-F and part of the shallow trench isolation STI, so that the first gate structure G covers a top surface and partial sidewalls of the first fin structure PG-F and forms a pass gate transistor (PG) of the SRAM, and forming a protrusion part (20, 24 or 26) located directly below the first gate structure G and on the shallow trench isolation STI, the protrusion part (20, 24 or 26) covers part of the surface of at least one sidewall of the first fin structure PG-F, and a top surface of the protrusion part (20, 24 or 26) is higher than the shallow trench isolation STI. The vertical height from the top surface of shallow trench isolation STI to the top surface of the first fin structure PG-F is defined as h1, and the vertical height from the top surface of shallow trench isolation STI to the top surface of the protrusion part (20, 24 or 26) is defined as h2.

In some embodiments of the present invention, when viewed from a cross-sectional view (refer to the embodiments in FIGS. 3 to 8), the protrusion parts (20, or 24) cover part of the sidewalls of the first fin structure PG-F, wherein the top width of the first fin structure PG-F is defined as w1, and the effective channel width of the pass gate transistor PG formed by the first gate structure G covering the first fin structure PG-F is w1+2 (h1−h2).

In some embodiments of the present invention, as viewed from a cross-sectional view (please refer to the cross-sectional structure in FIG. 9), the protrusion part 26 only covers part of the surface of one sidewall of the first fin structure PG-F, wherein the top width of the first fin structure PG-F is defined as w1, and the effective channel width of the pass gate transistor PG formed by the first gate structure G covering the first fin structure PG-F is w1+2h1−h2.

In some embodiments of the present invention, a second fin structure PD-F is connected to the silicon substrate and protrudes from the shallow trench isolation STI, and a second gate structure G spans the second fin structure PD-F and part of the shallow trench isolation STI, so that the second gate structure G covers a top surface and partial sidewalls of the second fin structure PD-F and forms a pull-down transistor (PD) of the SRAM.

In some embodiments of the present invention, there is no protrusion part (20, 24 or 26) between a region directly below the second gate structure G of the pull-down transistor PD and the shallow trench isolation STI, wherein the top surface T2 of the first fin structure PG-F and the top surface T2 of the second fin structure PD-F are aligned with each other in a horizontal direction, and a bottom surface of the first fin structure PG-F (i.e., the top surface T1 of the substrate S) and a bottom surface of the second fin structure PD-F are aligned with each other in the horizontal direction.

In some embodiments of the present invention, the width of the top surface of the second fin structure PD-F is defined as w1, the height from the top surface of the shallow trench isolation STI to the top surface of the second fin structure PD-F in the vertical direction is defined as h1, and the effective channel width of the pull-down transistor PD formed by the second gate structure G covering the second fin structure PD-F is w1+2h1.

In some embodiments of the present invention, the material of the protrusion part (24 or 26) is different from that of the shallow trench isolation STI.

In some embodiments of the present invention, the method for forming the protrusion part (24 or 26) includes: after the shallow trench isolation STI is formed, forming a material layer 22 on the shallow trench isolation STI, performing a patterning step, and removing part of the material layer, and defining the remaining material layer as the protrusion part (24 or 26).

In some embodiments of the present invention, the material of the protrusion part 20 is the same as that of the shallow trench isolation STI, and the protrusion part 20 and the shallow trench isolation STI are integrally formed structure.

In some embodiments of the present invention, the method of forming the protrusion part 20 includes: after the shallow trench isolation STI is formed, forming a mask layer HM on the shallow trench isolation STI, performing a patterning step, removing part of the shallow trench isolation STI not covered by the mask layer HM, and defining the part of the shallow trench isolation STI covered by the mask layer as the protrusion part 20.

The invention is characterized in that in order to improve the device quality, it is necessary to increase the ratio of the turn-on current of the PD transistor to the turn-on current of the PG transistor, but the width of the fin structure formed by sidewall pattern transfer cannot be adjusted only by the mask pattern. Therefore, the invention adjusts the channel width of the transistor by changing the shallow trench isolation around the fin structure or the height of the protrusion part. More specifically, the invention uses etching process to reduce shallow trench isolation beside other transistors except the PG transistor, or uses another mask layer to cover the PG fin structure, so that when the gate structure is covered on the fin structure, the channel width of the PD transistor will be larger the channel width of the PG transistor, thereby reducing the turn-on current of the PG transistor and achieving the purpose of improving the beta value and static noise margin of SRAM.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory structure, comprising:
a silicon substrate;
a shallow trench isolation located on the silicon substrate;
a first fin structure connected to the silicon substrate and protruding from the shallow trench isolation;
a first gate structure across the first fin structure and part of the shallow trench isolation, so that the first gate structure covers a top surface and part of sidewalls of the first fin structure, and constitutes a pass gate transistor (PG) of the SRAM; and
a protrusion part located directly below the first gate structure and on the shallow trench isolation, covering part of the surface of at least one sidewall of the first fin structure, wherein a top surface of the protrusion part is higher than a top surface of the shallow trench isolation, and a height from the top surface of the shallow trench isolation to the top surface of the first fin structure in a vertical direction is defined as h1, and a height from the top surface of the shallow trench isolation to the top surface of the protrusion part in the vertical direction is defined as h2.

2. The SRAM structure according to claim 1, wherein, when viewed from a cross section view, the protrusion part covers part of the surface of both sidewalls of the first fin structure, wherein a width of the top surface of the first fin structure is defined as w1, and the effective channel width of the pass gate transistor formed by the first gate structure covering the first fin structure is w1+2 (h1−h2).

3. The SRAM structure according to claim 1, wherein viewed from a cross section view, the protrusion part only covers part of the surface of one sidewall of the first fin structure, wherein a width of the top surface of the first fin structure is defined as w1, and the effective channel width of the pass gate transistor formed by the first gate structure covering the first fin structure is w1+2h1−h2.

4. The SRAM structure according to claim 1, further comprising:
a second fin structure connected to the silicon substrate and protruding from the shallow trench isolation; and
a second gate structure across the second fin structure and part of the shallow trench isolation, so that the second gate structure covers a top surface and part of sidewalls of the second fin structure, and constitutes a pull-down transistor (PD) of the SRAM.

5. The SRAM structure according to claim 4, wherein the protrusion part is not included between a region directly below the second gate structure and the shallow trench isolation, wherein the top surface of the first fin structure and the top surface of the second fin structure are aligned with each other in a horizontal direction, and a bottom surface of the first fin structure and a bottom surface of the second fin structure are aligned with each other in the horizontal direction.

6. The SRAM structure according to claim 5, wherein a width of the top surface of the second fin structure is defined as w1, a height from the top surface of the shallow trench isolation to the top surface of the second fin structure in the vertical direction is defined as h1, and the effective channel width of the pull-down transistor formed by the second gate structure covering the second fin structure is w1+2h1.

7. The SRAM structure according to claim 1, wherein the condition of 0<h2/h1<0.5 is satisfied.

8. The SRAM structure according to claim 1, wherein the material of the protrusion part is different from the material of the shallow trench isolation.

9. The SRAM structure according to claim 1, wherein the material of the protrusion part is the same as the material of the shallow trench isolation, and the protrusion part and the shallow trench isolation are integrally formed structure.

10. A method for fabricating a static random access memory structure, comprising:
providing a silicon substrate;
forming a shallow trench isolation on the silicon substrate;
forming a first fin structure connected to the silicon substrate and protruding from the shallow trench isolation;
forming a first gate structure across the first fin structure and part of the shallow trench isolation, so that the first gate structure covers a top surface and part of sidewalls of the first fin structure, and constitutes a pass gate transistor (PG) of the SRAM; and
forming a protrusion part directly below the first gate structure and on the shallow trench isolation, covering part of the surface of at least one sidewall of the first fin structure, wherein a top surface of the protrusion part is higher than a top surface of the shallow trench isolation, and a height from the top surface of the shallow trench isolation to the top surface of the first fin structure in a vertical direction is defined as h1, and a height from the top surface of the shallow trench isolation to the top surface of the protrusion part in the vertical direction is defined as h2.

11. The manufacturing method of the SRAM structure according to claim 10, wherein when viewed from a cross section view, the protrusion part covers part of the surface of both sidewalls of the first fin structure, wherein a width of the top surface of the first fin structure is defined as w1, and the effective channel width of the pass gate transistor formed by the first gate structure covering the first fin structure is w1+2 (h1−h2).

12. The manufacturing method of the SRAM structure according to claim 10, wherein viewed from a cross section view, the protrusion part only covers part of the surface of one sidewall of the first fin structure, wherein a width of the top surface of the first fin structure is defined as w1, and the effective channel width of the pass gate transistor formed by the first gate structure covering the first fin structure is w1+2h1−h2.

13. The method for manufacturing the SRAM structure according to claim 10, further comprising:
forming a second fin structure connected to the silicon substrate and protruding from the shallow trench isolation; and
forming a second gate structure across the second fin structure and part of the shallow trench isolation, so that the second gate structure covers a top surface and part of sidewalls of the second fin structure, and constitutes a pull-down transistor (PD) of the SRAM.

14. The manufacturing method of the SRAM structure according to claim 13, wherein the protrusion part is not included between a region directly below the second gate structure and the shallow trench isolation, wherein the top surface of the first fin structure and the top surface of the second fin structure are aligned with each other in a horizontal direction, and a bottom surface of the first fin structure and a bottom surface of the second fin structure are aligned with each other in the horizontal direction.

15. The manufacturing method of the SRAM structure according to claim 14, wherein a width of the top surface of the second fin structure is defined as w1, a height from the top surface of the shallow trench isolation to the top surface of the second fin structure in the vertical direction is defined as h1, and the effective channel width of the pull-down transistor formed by the second gate structure covering the second fin structure is w1+2h1.

16. The method for manufacturing a SRAM structure according to claim 10, wherein the condition of 0<h2/h1<0.5 is satisfied.

17. The manufacturing method of the SRAM structure according to claim 10, wherein the material of the protrusion part is different from the material of the shallow trench isolation.

18. The method for manufacturing the SRAM structure according to claim 17, wherein the method for forming the protrusion part comprises:
forming a material layer on the shallow trench isolation after the shallow trench isolation is formed;
performing a patterning step to remove part of the material layer, and defining the remaining material layer as the protruding part.

19. The manufacturing method of the SRAM structure according to claim 10, wherein the material of the protrusion part is the same as the material of the shallow trench isolation, and the protrusion part and the shallow trench isolation are integrally formed structure.

20. The method for manufacturing the SRAM structure according to claim 19, wherein the method for forming the protrusion part comprises:
forming a mask layer on the shallow trench isolation after the shallow trench isolation is formed;
performing a patterning step to remove part of the shallow trench isolation not covered by the mask layer, and defining a part of the shallow trench isolation covered by the mask layer as the protrusion part.
